(19) United States
(12) Patent Application Publication
(10) Pub. No.: US 2007/0260951 A1
(43) Pub. Date: Nov. 8, 2007

(54) Uncompromised standard input set-up time with improved enable input set-up time characteristics in a storage circuit

(75) Inventors: Ramakrishnan Karungulam Subramanian, Chennai (IN); Abhishek Chakraborty, Bangalore (IN)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/416,607

(22) Filed: May 3, 2006

(51) Int. Cl. G01R 31/28

(52) U.S. Cl. 714/726

(57) ABSTRACT

A method and/or system of uncompromised standard input set-up time with improved enable input set-up time characteristics in a storage circuit are disclosed. In one embodiment, a storage circuit includes a master latch coupled to a slave latch where each undergoes data transmission at an opposite transition edge of a clock cycle, an input multiplexer to apply the scan input data and/or a standard input data to the storage circuit based on a state of a scan signal, and a latch multiplexer in the master latch to apply an input multiplexer output data and a previous clock cycle output data to the storage circuit based on the state of the scan signal, a state of the enable signal, and/or a state of a current clock cycle timing signal.

### FIELD OF TECHNOLOGY

This disclosure relates generally to the technical fields of electronics and digital circuit technology and, in one example embodiment, to a method and/or a system of uncompromised standard input set-up time with improved enable input set-up time characteristics in a storage circuit.

### BACKGROUND

A storage circuit (e.g., a standard flip-flop, an enable flip-flop, a scan flip-flop, and enable flip-flop with scan, etc.) may be a clocked digital circuit capable of serving as a one-bit memory. The standard flip-flop may be operated in two states (e.g., a zero state and a one state). The standard flip-flop may include a timing signal (e.g., controlled by a clock) and a data signal at an input to the standard flip-flop. When the timing signal is turned high, a stable data (e.g., data at the input before a set-up time of the flip-flop) may be transferred to an output of the standard flip-flop after a clock-to-Q delay of the standard flip-flop.

A synchronous-sequential circuit (a synchronous circuit in short) may be a digital circuit (e.g., an electronic circuit based on a number of discrete voltage levels) having sub-circuits that are synchronized (e.g., operated in unison) by flip-flops (e.g., may be used to coordinate actions of two or more sub-circuits). In the synchronous circuit, a timing signal (e.g., an external signal generated from a crystal oscillator and/or a timer etc.) may be used to simultaneously trigger a chain of standard flip-flops and other logic units (e.g., a combinational circuit).

The timing signal may oscillate between a high voltage and a low voltage and the standard flip-flop may transfer data between various sub-circuits of the synchronous circuit at either a rising edge and/or a falling edge of the timing signal. For proper operation of the synchronous circuit, propagation delays may be accounted for (e.g., a set up time, a clock-to-Q delay, etc.). The propagation delays may limit a maximum frequency (e.g., speed) of the synchronous circuit. Any stable data available at the input of each standard flip-flop one set-up time before a clock-edge hits the standard flip-flop, may be stably and/or reliably transferred to the output of the standard flip-flop after one clock-to-Q delay of the standard flip-flop.

The scan flip-flop may be a variation of the standard flip-flop designed to include additional testing circuitries and/or features. The scan flip-flop can make it easier to validate that the synchronous circuit contains no defect that could adversely affect the synchronous circuit's correct functioning. An objective of the scan flip-flop may be to make testing easier by providing a way to precisely set inputs to known values and observe the output of every scan flip-flop in the synchronous circuit.

As such, a special signal called a scan signal may be added to each scan flip-flop in the synchronous circuit. When the scan signal is asserted, an arbitrary pattern can be entered into each scan flip-flop in the synchronous circuit from an alternate input signal (e.g., a test input ‘TI’), and a state of every scan flip-flop can be read out from the output (e.g., an alternate output ‘TO’). When the scan signal is not asserted, the stable data from the standard input may be transferred to the output of the scan flip-flop.

The scan-flip-flop can have higher set-up time as compared to the standard flip-flop because of added circuitry used to select from the standard input and the test input (TI) of the scan flip-flop. When the scan signal is asserted, data available at the alternate input signal may be transferred to the output on a next clock edge. Even when the scan signal is not asserted, the additional delay can hamper performance because data bits may have to pass through additional circuitry of the scan flip-flop. This delay may reduce a maximum operating frequency of the synchronous circuit because the set-up time in the scan-flip-flop may be increased (as compared to the standard flip-flop), and therefore the stable data may need to arrive earlier to be transferable by the scan flip-flop.

An additional variation of the standard flip-flop (e.g., enable flip-flop) may include a capability to re-use an output of the standard flip-flop of a previous clock cycle in addition to processing the standard input . As such, an additional input (e.g., an enable input) may be added to each standard flip-flop in the synchronous circuit to facilitate a selection of the output of the standard flip-flop of a previous clock cycle. As a result of the additional circuitry needed to process the additional input (e.g., the enable input), the set-up time of the standard input may also be compromised.

The enable flip-flop may have an asynchronous input (preset signal) that presets the output (e.g., sets to one-state) asynchronously (e.g., independent of clock) when asserted and/or an asynchronous input (e.g., clear signal) that clears the output (e.g., sets to zero-state) asynchronously (e.g., independent of clock) when asserted.

An additional variation of the scan flip-flop (e.g., an enable scan flip-flop) may include a capability to re-use an output of the scan flip-flop of a previous clock cycle in addition to processing the standard input and the test input. As such, an additional input (e.g., an enable input) may be added to each scan flip-flop in the synchronous circuit to facilitate a selection of the output of the scan flip-flop of a previous clock cycle. As a result of the additional circuitry needed to process the additional input (e.g., the enable input), the set-up time of the standard input may also be compromised.

The enable scan flip-flop may have an asynchronous input (e.g., preset signal) that resets the output (e.g., sets to one-state) asynchronously (e.g., independent of clock) when asserted and/or an asynchronous input (e.g., clear signal) that clears the output (e.g., sets to zero-state) asynchronously (e.g., independent of clock) when asserted (e.g., activated).

### SUMMARY

A method and/or a system of uncompromised standard input set-up time with improved enable input set-up time characteristics in a storage circuit are disclosed. In one aspect, a digital system includes storage circuits interconnected together with logic circuitry to form at least a portion of a functional circuit, with each of the storage circuits having a standard input data and a previous clock cycle output data, and an enable signal to control a mode of operation.

In this aspect, each of the storage circuits include a master latch coupled to a slave latch where each undergoes data transmission at an opposite transition edge of a clock cycle and a latch multiplexer in the master latch to apply an input multiplexer output data and the previous clock cycle output data to the storage circuit based on a state of a scan signal, a state of the enable signal, and/or a state of a current clock cycle timing signal. The master latch may include an input transmission gate and a hold loop having the latch multiplexer, an inverter, and a loop transmission gate, wherein the hold loop undergoes data transmission at an opposite transition edge of the clock cycle from the input transmission gate.

In this aspect, each of the enable flip-flop may include a master latch coupled to a slave latch where each undergoes data transmission at an opposite transition edge of a clock cycle. The master latch may include an input transmission gate and a hold loop having the latch multiplexer, an inverter, and a loop transmission gate, wherein the hold loop undergoes data transmission at an opposite transition edge of the clock cycle from the input transmission gate. A latch multiplexer in the master latch may apply the input transmission gate output data or the previous clock cycle output data to the storage circuit based on the state of the scan signal, a state of the enable signal, and/or a state of a current clock cycle timing signal.

The latch multiplexer select signal may be controlled by a combinational logic output data which in turn is controlled by the state of the scan signal and the state of the enable signal. A set-up time of the enable signal may be reduced by approximately 50% when the hold loop in the master latch is synchronously closed and the scan signal is low. The previous clock cycle output data of the storage circuit may change when a clock edge corresponding to the current clock cycle is reached. A set-up time of the standard input may not increase from a design not having the enable signal.

In another aspect, an enable flip-flop includes a timing signal corresponding to any clock cycle to facilitate any data transfer from an enable flip-flop input to an enable flip-flop output. In addition, a scan signal and an enable signal may control a mode of operation of the enable flip-flop. A master latch may process a standard input data, a scan input data and/or a previous clock cycle output data based on a state of the scan signal, a state of the enable signal, and a state of a current clock cycle timing signal. A slave latch may be coupled to a master latch output data controlled by a current clock cycle timing signal.

In this aspect, in an enable flip-flop, an input multiplexer may apply the scan input data and/or the standard input data to the master latch based on the state of the scan signal. A master latch multiplexer may apply an input transmission gate output data and/or the previous clock cycle output data to the master latch based on the state of the scan signal, the state of the enable signal, and/or the state of the current clock cycle timing signal. The scan input data may be transmitted to the enable flip-flop output when the scan signal is enabled. The standard input data may be transmitted to the enable flip-flop output when the scan signal is disabled and the enable signal is enabled.

In an enable flip-flop, a previous clock cycle output data may be transmitted to the enable flip-flop output when the scan signal is disabled and the enable signal is enabled. A set-up time of the standard input data may not increase compared to a flip-flop without an enable signal. A physical location where the previous clock cycle output data may be fed-back may enable a reduction in a set-up time of the enable signal. The set-up time of the enable signal may be reduced by bypassing a delay of the input multiplexer and the input transmission gate. The set-up time of the enable signal may be reduced by approximately 50%.

In yet another aspect, in the enable flip-flop without scan, a method includes generating a current clock cycle output data based on a state of an enable signal, and a state of a current clock cycle timing signal, and applying a previous clock cycle output data to a latch multiplexer of a master latch based on the state of the enable signal, and the current clock cycle timing signal. The previous clock cycle output data may not change until a current clock edge is reached.

In addition, in an enable flip-flop, the method may include reducing a set-up time of the enable signal by applying the previous clock cycle output data to the latch multiplexer based on the state of the scan signal, the enable signal, and the current clock cycle timing signal. A propagation delay associated with an input multiplexer and an input transmission gate may be reduced from the set-up time of the enable signal. The set-up time of the enable signal may be reduced by approximately 50% from a design not applying the previous clock cycle output data to the multiplexer of the master latch. The set-up time of a standard input may not increase from a design not applying the previous clock cycle output data to the latch multiplexer of the master latch.

The methods, systems, and apparatuses disclosed herein may be implemented in any means medium embodying a set of instructions that, may be executed in a form of a machine-readable medium embodying a set of instruction that, when executed by a machine, cause the machine to perform any of the operations disclosed herein. Other features will be apparent from the accompanying drawings and from the detailed description that follows.

### BRIEF DESCRIPTION OF THE DRAWINGS

Example embodiments are illustrated by way of example and not limitation in the figures of the accompanying drawings, in which like references indicate similar elements and in which:

FIG. 1 is a block diagram of a scan flip-flop with enable between combinational circuits, according to one embodiment.

FIG. 2 is a circuit diagram of the scan flip-flop with enable of FIG. 1, according to one embodiment.

FIG. 3 is a circuit diagram of a scan flip-flop with enable with exploded circuitry of a master latch and a slave latch, according to one embodiment.

FIG. 4 is a process flow of applying a previous clock cycle output data to a latch multiplexer of a master latch based on the state of the scan signal, the enable signal, and the current clock cycle timing signal, according to one embodiment.

FIG. 5 is a table view of a timing table, according to one embodiment.

Other features of the present embodiments will be apparent from the accompanying drawings and from the detailed description that follows.

### DETAILED DESCRIPTION

A method and/or a system of uncompromised standard input set-up time with improved enable input set-up time characteristics in a storage circuit are disclosed. In the following description, for the purposes of explanation, numerous specific details are set forth in order to provide a thorough understanding of the various embodiments. It will be evident, however to one skilled in the art that the various embodiments may be practiced without these specific details.

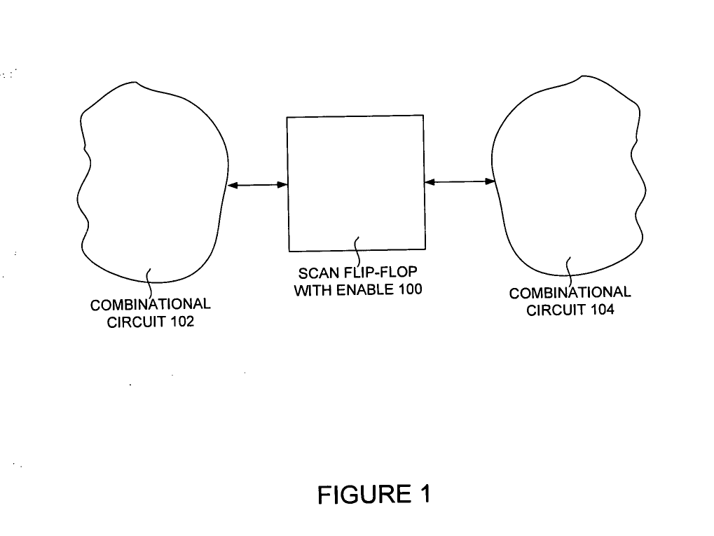

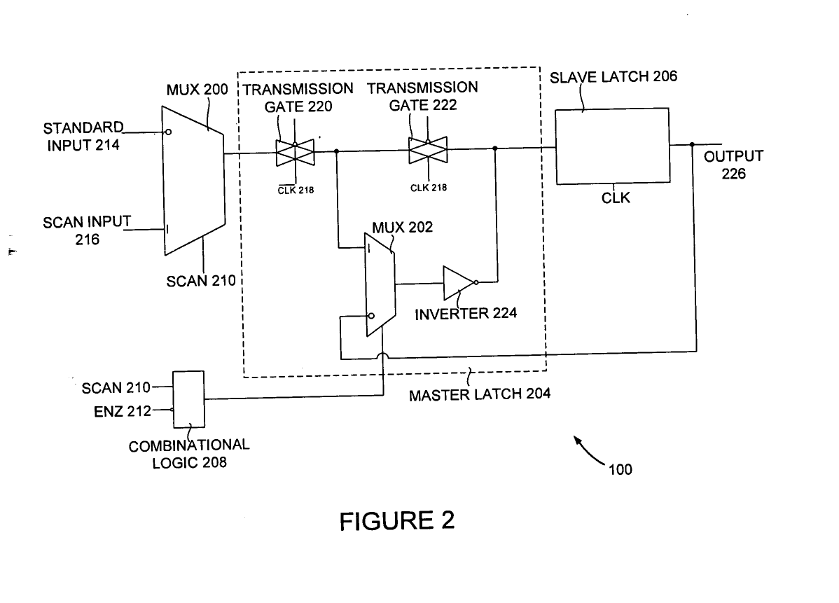

In one embodiment, a digital system includes storage circuits interconnected together with logic circuitry to form at least a portion of a functional circuit (e.g., as illustrated in FIG. 1), with each of the storage circuits (e.g., the scan flip-flop with enable 100 of FIG. 2) having a scan input data, a standard input data and a previous clock cycle output data, a scan signal and an enable signal to control a mode of operation. In this aspect, each of the storage circuits include a master latch (e.g., a master latch 204 of FIG. 2) coupled to a slave latch (e.g., a slave latch 206 of FIG. 2) where each undergoes data transmission at an opposite transition edge of a clock cycle, an input multiplexer (e.g., an input multiplexer 200 of FIG. 2) to apply the scan input data and/or the standard input data to the storage circuit based on a state of the scan signal, and a latch multiplexer (e.g., a latch multiplexer 202 of FIG. 2) in the master latch to apply an input transmission gate (e.g., the input transmission gate 220) output data or the previous clock cycle output data to the storage circuit based on the state of the scan signal, a state of the enable signal, and/or a state of a current clock cycle timing signal.

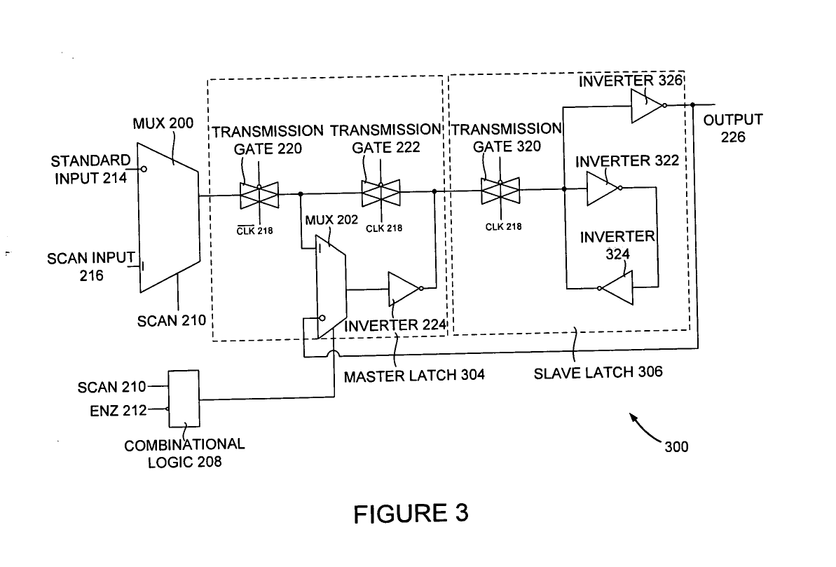

In another embodiment, an enable flip-flop (e.g., the scan flip-flop with enable 300 of FIG. 3) includes a timing signal corresponding to any clock cycle to facilitate any data transfer from an enable flip-flop input to an enable flip-flop output. In addition, a scan signal and an enable signal may control a mode of operation of the enable flip-flop. A master latch (e.g., a master latch 304 of FIG. 3) may process a standard input data, a scan input data and/or a previous clock cycle output data based on a state of the scan signal, a state of the enable signal, and a state of a current clock cycle timing signal. A slave latch (e.g., a slave latch 306 of FIG. 3) may be coupled to a master latch output data controlled by a current clock cycle timing signal.

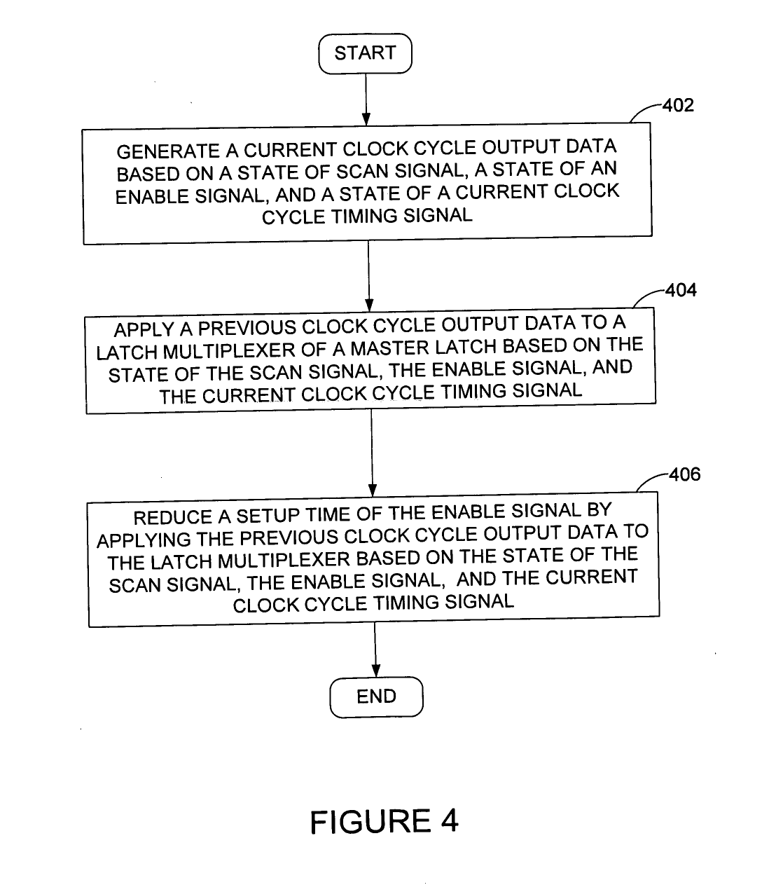

In yet another embodiment, a method includes generating a current clock cycle output data based on a state of a scan signal, a state of an enable signal, and a state of a current clock cycle timing signal, and applying a previous clock cycle output data to a latch multiplexer of a master latch based on the state of the scan signal, the enable signal, and the current clock cycle timing signal (e.g., as described in FIG. 4)

FIG. 1 is a block diagram of scan flip-flop with enable 100 (e.g., a storage circuit) between combinational circuits (e.g., a combinational circuit 102 and a combinational circuit 104), according to one embodiment. The combinational circuit 102 and/or the combinational circuit 104 may be logic circuits (e.g., having any number of gates, transistors, etc.) that communicate with each other through the scan flip-flop with enable 100 (e.g., may form at least a portion of a functional circuit). The enable flip-flop can be understood with reference to FIG. 2. FIG. 2 is a circuit diagram of the scan flip-flip flop with enable 100 of FIG. 1, according to one embodiment. A master latch 204 is coupled with a slave latch 206 in FIG. 2. In one embodiment, the master latch 204 is coupled to a slave latch where each undergoes data transmission at an opposite transition edge of a clock cycle (e,g., the clock 218 as illustrated in FIG. 2). The master latch 204 is coupled to an input multiplexer 200 and a combinational logic 208. The combinational logic 208 may be controlled by the state of a scan signal 210 and the state of the enable signal 212 (e.g., the scan input data associated with the scan signal 210 may transmitted to an output 226 of the scan flip-flop with enable 100 when the scan signal 210 is enabled).

The input multiplexer 200 selects either a standard input 214 and/or a scan input 216 based on the scan signal 210 (e.g., may apply any one of the scan input data and the standard input data based on a state of the scan signal). The combinational logic 208 may include circuitry (e.g., an ‘OR’ gate) that enables a latch multiplexer 202 of the master latch 204 to select the input transmission gate (e.g., the input transmission gate 220) output when either the scan signal 210 is asserted or the enable signal 212 is asserted (e.g., in a low state).

The master latch 204 includes an input transmission gate 220 (e.g., clocked by a falling edge of a clock 218), a loop transmission gate 222 (e.g., clocked by a rising edge of the clock 218), the latch multiplexer 202, and an inverter 224. The latch multiplexer 202 may select between an output of the input transmission gate 220 and an output 226 of the slave latch 206, as illustrated in the embodiment of FIG. 2 (e.g., the latch multiplexer 202 may apply any one of an input multiplexer output data and the previous clock cycle output data based on the state of the scan signal, a state of the enable signal, and a state of a current clock cycle timing signal).

The loop transmission gate 222, the latch multiplexer 202, and the inverter 224 may form a hold loop as illustrated in FIG. 2. The hold loop may undergo data transmission at an opposite transition edge of the clock cycle (e.g., of the clock 218) from the input transmission gate 220. A set-up time of the enable signal 212 may reduced by approximately 50% when the hold loop in the master latch is synchronously closed with the clock 218 and the scan signal is low (e.g., because a set-up time of the input multiplexer 200 and the input transmission gate 220 is bypassed). It should be noted that a set-up time of the standard input 214 may not increase from a design not having the enable signal 212 (e.g., a physical location where the previous clock cycle output data is fed-back may provide a reduction in a set-up time of the enable signal 212).

The previous clock cycle output data (e.g., the output 226) of the scan flip-flop with enable 100 of FIG. 2 may change when a clock edge corresponding to the current clock cycle is reached (e.g., the output 226 is coupled to the latch multiplexer 202 as illustrated in FIG. 2). The previous clock cycle output data may be transmitted to the output 226 when the scan signal 210 is disabled and the enable signal 212 is enabled according to one embodiment. A timing signal (e.g., associated with the clock 218) corresponding to any clock cycle (e.g., a high and/or a low state) may facilitate (e.g., cause) any data transfer from an enable flip-flop input (e.g., the input of the master latch 204 of FIG. 2) to an enable flip-flop output (e.g., the output 226 of FIG. 2). A scan signal and an enable signal may control a mode of operation of the enable flip-flop, according to one embodiment.

FIG. 3 is a circuit diagram of a scan flip-flop with enable 300 with exploded circuitry of a master latch 304 and a slave latch 306, according to one embodiment. The scan flip-flop with enable 300 of FIG. 3 is similar to the scan flip-flop with enable 100 of FIG. 2 with a circuitry of the slave latch 306 in exploded form. For example, the slave latch 306 (e.g., a slave latch may be coupled to a master latch output data controlled by a current clock cycle timing signal) includes an input transmission gate 320, an inverter 322, an inverter 324, and an inverter 326 as illustrated in FIG. 3. The input transmission gate 320 is illustrated as timed by a rising edge of the clock 218 (e.g., as compared to the input transmission gate 220 of the master latch 304 being timed by a falling edge of the clock 218).

FIG. 4 is a process flow of applying a previous clock cycle output data to a latch multiplexer (e.g., the latch multiplexer 202 of FIG. 2) of a master latch (e.g., the master latch 204 of FIG. 2) based on the state of the scan signal (e.g., the scan signal 210), the enable signal (e.g., the enable signal 212 of FIG. 2), and the current clock cycle timing signal (e.g., a timing signal of the clock 218 of FIG. 2), according to one embodiment. In operation 402, a current clock cycle output data may be generated based on a state of a scan signal (e.g., the scan signal 210 of FIG. 2), a state of an enable signal (e.g., the enable signal 212 of FIG. 2), and a state of a current clock cycle timing signal (e.g., of the clock 218 of FIG. 2).

In operation 404, a previous clock cycle output data (e.g., the previous clock cycle output data may not change until a current clock edge is reached) may be applied to a latch multiplexer (e.g., the latch multiplexer 202 of FIG. 2) of a master latch (e.g., the master latch 204 of FIG. 2) based on the state of the scan signal, the enable signal, and the current clock cycle timing signal. Then, in operation 406, a set-up time of the enable signal (e.g., the enable signal 212 of FIG. 2) may be reduced by applying the previous clock cycle output data to the latch multiplexer (e.g., the latch multiplexer 202 of FIG. 2) based on the state of the scan signal, the enable signal, and the current clock cycle timing signal (e.g., a propagation delay associated with an input multiplexer and an input transmission gate may reduced from the set-up time of the enable signal). For example, the set-up time of the enable signal may be reduced by approximately 50% from a design not applying the previous clock cycle output data to the multiplexer of the master latch. In addition, a set-up time of a standard input may not increased from a design not applying the previous clock cycle output data to the latch multiplexer of the master latch.

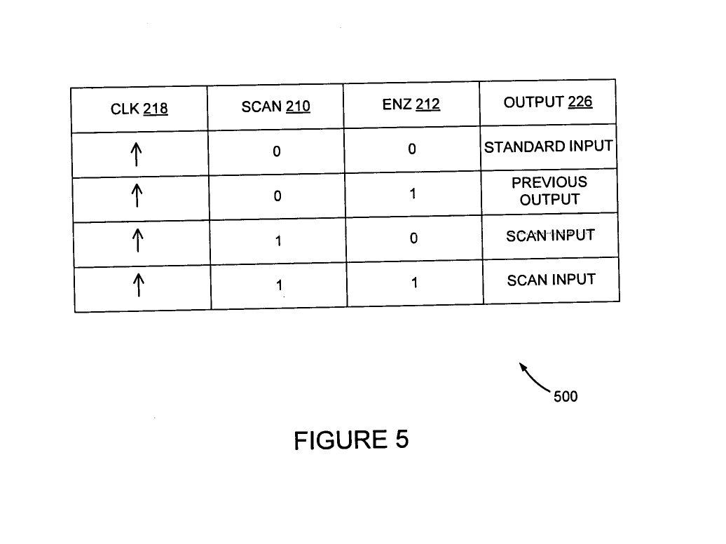

FIG. 5 is a table view of a timing table 500, according to one embodiment. The timing table 500 illustrates that when the clock 218 of FIG. 2 is high, when the scan signal 210 is low, and when the enable signal 212 is low, the output 226 of FIG. 2 is a standard input (e.g., the standard input 214 of FIG. 2). When the clock 218 of FIG. 2 is high, when the scan signal 210 is low, and when the enable signal 212 is high, the output 226 (e.g., of FIG. 2) is the previous output (e.g., ‘OUTPUT (N−1)’). When the clock 218 of FIG. 2 is high, when the scan signal 210 is high, and when the enable signal 212 is low, the output 226 (e.g., of FIG. 2) is the scan input (e.g., the scan input 216 of FIG. 2). Lastly, when the clock 218 of FIG. 2 is high, when the scan signal 210 is high, and when the enable signal 212 is high, the output 226 (e.g., of FIG. 2) is also the scan input (e.g., the scan input 216 of FIG. 2).

It should be noted that in one embodiment, the scan flip-flop with enable 100 of FIG. 2 and/or the scan flip-flop with enable 300 of FIG. 3 may be embodied using two or more storage circuits interconnected together with logic circuitry to form at least a portion of a functional circuit (e.g., an Application Specific Integrated Circuit ‘ASIC’, a Digital Signal Processor ‘DSP’, etc.). Multiple ones of the scan flip-flop with enable 100 of FIG. 2 and/or the scan flip-flop with enable 300 of FIG. 3 may form a partial scan, a multiple scan chain, and/or a test compression scan chain, etc.

Although the present embodiments have been described with reference to specific example embodiments, it will be evident that various modifications and changes may be made to these embodiments without departing from the broader spirit and scope of the various embodiments. For example, the various devices, modules, analyzers, generators, etc. described herein may be enabled and operated using hardware circuitry (e.g., CMOS based logic circuitry), firmware, software and/or any combination of hardware, firmware, and/or software (e.g., embodied in a machine readable medium). For example, the various electrical structure and methods may be embodied using transistors, logic gates, and electrical circuits (e.g., application specific integrated ASIC circuitry).

In addition, it will be appreciated that the various operations, processes, and methods disclosed herein may be embodied in a machine-readable medium and/or a machine accessible medium compatible with a data processing system (e.g., a computer system), and may be performed in any order. Accordingly, the specification and drawings are to be regarded in an illustrative rather than a restrictive sense.

The above mentioned embodiments can be extended to enable flip-flop without scan, enable flip-flop and asynchronous preset and/or clear inputs, enable flip-flop without scan and asynchronous preset and/or clear inputs. In all the above embodiments, positive edge triggered or rising edge triggered (input data is applied to the output at the rising edge of the clock signal) flip-flops have been illustrated. The above embodiments can also be extended to negative edge triggered or falling edge triggered flip-flops (input data is applied to the output at the falling edge of the clock signal)

What is claimed is:

1. A digital system, comprising:
a plurality of storage circuits interconnected together with logic circuitry to form at least a portion of a functional circuit, with each of the storage circuits having a standard input data and a previous clock cycle output data, an enable signal to control a mode of operation, with each of the storage circuits having:
a master latch coupled to a slave latch where each undergoes data transmission at an opposite transition edge of a clock cycle; and
a latch multiplexer in the master latch to apply any one of an input multiplexer output data and the previous clock cycle output data to the storage circuit based on the state of the scan signal, a state of the enable signal, and a state of a current clock cycle timing signal.

2. The digital system of claim 1 wherein the master latch comprises an input transmission gate and a hold loop comprising:
the latch multiplexer, an inverter, and a loop transmission gate, wherein the hold loop undergoes data transmission at an opposite transition edge of the clock cycle from the input transmission gate.

3. The digital system of claim 1 wherein the latch multiplexer is selected by a combinational logic output data controlled by the state of the enable signal.

4. The digital system of claim 1 wherein a set-up time of the enable signal is reduced by approximately 50% when the hold loop in the master latch is synchronously closed, the enable signal is high.

5. The digital system of claim 1 and 2 wherein the previous clock cycle output data of the storage circuit changes when a clock edge corresponding to the current clock cycle is reached.

6. The digital system of claim 1 and 2 wherein a set-up time of the standard input does not increase from a design not having the enable signal.

7. An enable flip-flop, comprising:
a timing signal corresponding to any clock cycle to facilitate any data transfer from an enable flip-flop input to an enable flip-flop output, and an enable signal to control a mode of operation of the enable flip-flop;
a master latch to process any of a standard input data, and a previous clock cycle output data based on a state of the enable signal, and a state of a current clock cycle timing signal;
a slave latch coupled to a master latch output data controlled by a current clock cycle timing signal; and
a master latch multiplexer to apply any one of an input transmission gate output data and the previous clock cycle output data to the master latch based on the state of the enable signal, and the state of the current clock cycle timing signal.

8. The enable flip-flop of claim 7 wherein the scan input data is transmitted to the enable flip-flop output when the scan signal is enabled.

9. The enable flip-flop of claim 7 wherein the standard input data is transmitted to the enable flip-flop output when the scan signal is disabled and the enable signal is enabled.

10. The enable flip-flop of claim 7 wherein a previous clock cycle output data is transmitted to the enable flip-flop output when the scan signal is disabled and the enable signal is disabled.

11. The enable flip-flop of claim 7 wherein a set-up time of the standard input data does not increase compared to a flip-flop without an enable signal.

12. The enable flip-flop of claim 7 wherein a physical location where the previous clock cycle output data is fed-back enables a reduction in a set-up time of the enable signal.

13. The enable flip-flop of claim 7 wherein the set-up time of the enable signal is reduced by bypassing a delay of the input transmission gate.

14. The enable flip-flop of claim 13 wherein the set-up time of the enable signal is reduced by approximately 50%.

15. A method, comprising:
generating a current clock cycle output data based on a state of a state of an enable signal, and a state of a current clock cycle timing signal;
applying a previous clock cycle output data to a latch multiplexer of a master latch based on the state of the enable signal, and the current clock cycle timing signal.

16. The method of claim 15 wherein the previous clock cycle output data cannot change until a current clock edge is reached.

17. The method of claim 15 further comprising reducing a set-up time of the enable signal by applying the previous clock cycle output data to the latch multiplexer based on the state of the enable signal, and the current clock cycle timing signal.

18. The method of claim 15 wherein a propagation delay associated with an input transmission gate is reduced from the set-up time of the enable signal.

19. The method of claim 15 wherein the set-up time of the enable signal is reduced by approximately 50% from a design not applying the previous clock cycle output data to the multiplexer of the master latch.

20. The method of claim 15 wherein a set-up time of a standard input is not increased from a design not applying the previous clock cycle output data to the latch multiplexer of the master latch.
